(19) United States
(12) Patent Application Publication
(10) Pub. No.: US 2025/0350293 A1
(43) Pub. Date: Nov. 13, 2025

(54) Two-stage Successive Approximation Register Analog to Digital Converter (SAR ADC) Based on Difference and Differential Amplifier

(71) Applicant: JIANGSU GTIC MICROELECTRONICS CO., LTD, Wuxi (CN)

(72) Inventors: Weibo HU, Wuxi (CN); Fangmin SHI, Wuxi (CN); Wei MA, Wuxi (CN); Xiang YAN, Wuxi (CN); Shangzheng YANG, Wuxi (CN); Meiyu WANG, Wuxi (CN)

(21) Appl. No.: 18/720,660

(22) PCT Filed: Jul. 5, 2023
(86) PCT No.: PCT/CN2023/105938

§ 371 Date: Jan. 9, 2025

(30) Foreign Application Priority Data
Dec. 6, 2022 (CN) 202211552902.7

(51) Int. Cl. H03M 1/10

(52) U.S. Cl. CPC H03M 1/1023

(57) ABSTRACT

Disclosed is a two-stage successive approximation register analog to digital converter based on a difference and differential amplifier, including a first-stage sub-ADC, a difference and differential amplifier, and a second-stage sub-ADC connected in sequence. The first-stage sub-ADC and the second-stage sub-ADC each include capacitor arrays and comparators. The difference and differential amplifier includes a transconductance amplifier GM1, a transconductance amplifier GM2, a resistance load R, and proportional resistors R1 and R2. The transconductance amplifier GM1, the resistance load R, and the transconductance amplifier GM2 form a negative feedback loop. The disclosure adjusts the gain of the amplifiers through the proportional resistors R1 and R2, so that higher conversion accuracy can be achieved.

### TECHNICAL FIELD

The disclosure relates to the field of analog to digital converters, and particularly relates to a two-stage successive approximation register analog to digital converter based on a difference and differential amplifier.

### BACKGROUND

A conventional single-stage successive approximation register analog to digital converter generates a residual voltage depending on a capacitive digital to analog converter (CDAC) and determines the polarity of the residual voltage through a comparator. With increase of accuracy, total capacitance of the analog to digital converter shows exponential growth, the residual voltage is also reduced to sub-millivolt, and the resolution is greatly affected by capacitance mismatch and comparator noise. To achieve an analog to digital converter with higher accuracy, a multi-stage SAR ADC is proposed. Different from a single-stage structure, the accuracy of the multi-stage SAR ADC is mainly limited to the gain error and the offset voltage of a residue amplifier (RA).

### SUMMARY

### Technical Problems

To overcome deficiencies in the related art, the disclosure provides a two-stage successive approximation register analog to digital converter based on a difference and differential amplifier. A two-stage SAR ADC architecture is formed by introducing the difference and differential amplifier as a residue amplifier. An offset voltage is eliminated through one-time calibration by means of the architecture, and a negative feedback is formed through a resistor network to provide a stable gain, so that higher conversion accuracy can be achieved.

### Technical Solution

To achieve the above object, a two-stage successive approximation register analog to digital converter based on a difference and differential amplifier provided by the disclosure includes a first-stage sub-ADC, a difference and differential amplifier, and a second-stage sub-ADC connected in sequence, where the first-stage sub-ADC and the second-stage sub-ADC each include capacitor arrays and comparators; and further includes a calibrating circuit and a digital logic control circuit, where the calibrating circuit is configured for one-time calibration of offset voltages of each of the amplifiers and the comparators, and the digital logic control circuit is configured to control work schedules of the two sub-ADCs;

the difference and differential amplifier includes a transconductance amplifier GM1, a transconductance amplifier GM2, a resistance load R, and proportional resistors R1 and R2; the transconductance amplifier GM1, the resistance load R, and the transconductance amplifier GM2 form a negative feedback loop, and the proportional resistors R1 and R2 are configured to regulate gains of the amplifiers; and specific working steps based on the above architecture are as follows:
step I, switching on a switch S1, where signal voltages are stored in the capacitor arrays of the first-stage sub-ADC;
step II, switching off the switch S1, where the capacitor arrays of the first-stage sub-ADC will be flipped in sequence, charges stored in the capacitor arrays will be redistributed, and a voltage difference between input ends of the transconductance amplifier GM1 will be gradually decreased;
step III, in a case that a last pair of capacitors in the capacitor array of the first-stage sub-ADC are flipped, switching on a switch S2, where the capacitor array of the second-stage sub-ADC will store a voltage outputted by a residue amplifier;
step IV, switching off the switch S2, where the capacitor arrays of the second-stage sub-ADC will be flipped in sequence to redistribute the charges and reduce the voltage difference; and
step V, integrating flipping conditions of the capacitor arrays of the first-stage and second-stage sub-ADCs to output a finally quantified signal.

Further, a working process of the two-stage successive approximation register analog to digital converter based on a difference and differential amplifier includes: first, roughly digitizing a differential input signal and generating a residual voltage through the first-stage sub-ADC; then amplifying the residual voltage through the difference and differential amplifier; then further digitalizing the residual voltage through the second-stage sub-ADC; and finally, correcting and combining outputs of the two sub-ADCs in an output circuit to generate a 16-bit digital output.

Further, a specific working process of the difference and differential amplifier includes: first, converting the residual voltage that is generated by the first-stage sub-ADC and passes through the transconductance amplifier GM1 into a current signal lip; then passing the current signal Ii_{P} through the resistance load R and outputting a voltage signal V_{O}; and finally, by taking the V_{O} divided by the proportional resistors R1 and R2 as an input of the transconductance amplifier GM2, outputting a Ii_{N} to regulate a current flowing through the resistance load, so as to regulate an output voltage V_{O}.

Further, the output currents of the transconductance amplifier GM1 and the transconductance amplifier GM2 are respectively:

$${Ii}_{P} = {G}_{m 1} \cdot ( {V i}_{P} - {V i}_{N} )$$

$${Ii}_{N} = - V o \cdot \frac{R 2}{R 1 + R 2} \cdot {G}_{m 2}$$

where Gₘ₁ and Gₘ₂ respectively represent transconductance values of the transconductance amplifier GM1 and the transconductance amplifier GM2.

Further, the output voltage of the difference and differential amplifier is:

$$V o = R \cdot ( {Ii}_{P} + {Ii}_{N} )$$

Further, the gain of the difference and differential amplifier is:

$$Gain = \frac{{G}_{m 1}}{\frac{1}{R} + \frac{R 2}{R 1 + R 2} \cdot {G}_{m 2}}$$

in a case that 1/Gₘ₁=1/Gₘ₂<<R, the above equation can be simplified as:

$$Gain \approx 1 + \frac{R 1}{R 2}$$

where the gain of the amplifier is flexibly regulated by regulating a resistance proportion of R1 and R2.

### Beneficial Effects

The two-stage successive approximation register analog to digital converter based on a difference and differential amplifier provided by the disclosure at least includes the following advantages:

1. The two-stage SAR ADC architecture is formed by introducing the difference and differential amplifier as the residue amplifier, so that the gain error is effectively reduced, and the accuracy of the analog to digital converter is improved.

2. Compared with a conventional closed-loop amplifier structure based on capacitive feedback, a smaller size and a lower cost are achieved.

3. Compared with a closed-loop amplifier structure based on resistance feedback, it is of not need to arrange a buffer stage additionally, thereby not resulting in charge leakage.

4. Compared with a structure based on an open-loop GM-R amplifier, the solution has more stable performance and can achieve higher conversion accuracy.

### BRIEF DESCRIPTION OF FIGURES

FIG. 1 is a schematic diagram of a circuit of an analog to digital converter based on a difference and differential amplifier;

FIG. 2 is a structural diagram of an analog to digital converter architecture proposed in this application;

FIG. 3 is a structural diagram of an existing residue amplifier structure; and

FIG. 4 is a structural diagram of a circuit based on the difference and differential amplifier.

### DETAILED DESCRIPTION

The disclosure will be further described below in conjunction with drawings.

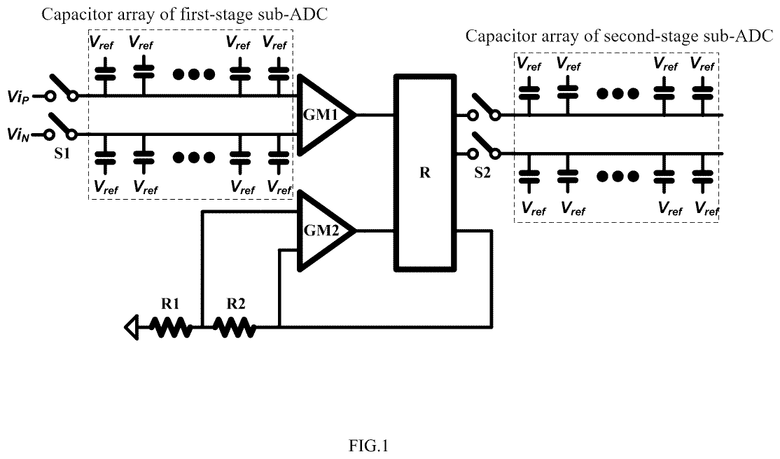

A two-stage successive approximation register analog to digital converter based on a difference and differential amplifier shown in FIG. 1 includes a first-stage sub-ADC, a difference and differential amplifier, and a second-stage sub-ADC connected in sequence, where the first-stage sub-ADC and the second-stage sub-ADC each include capacitor arrays and comparators; and further includes a calibrating circuit and a digital logic control circuit, where the calibrating circuit is configured for one-time calibration of offset voltages of each of the amplifiers and the comparators, and the digital logic control circuit is configured to control work schedules of the two sub-ADCs.

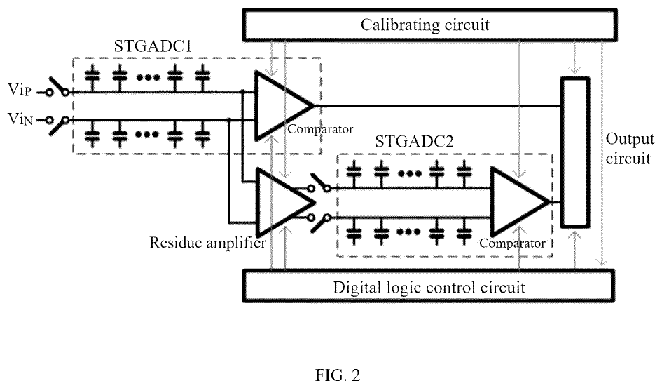

As same as a conventional architecture, the analog to digital converter proposed in this application, shown in FIG. 2, includes two sub-ADCs STGADC1 and STGADC2, a residue amplifier, a digital logic control circuit, and a calibrating circuit. To achieve the purpose of low noise and high linearity, the STGADC1 usually has a large area and high power. The STGADC2 minimizes the area cost and the capacitive load of the residue amplifier on the premise of keeping a necessary resolution.

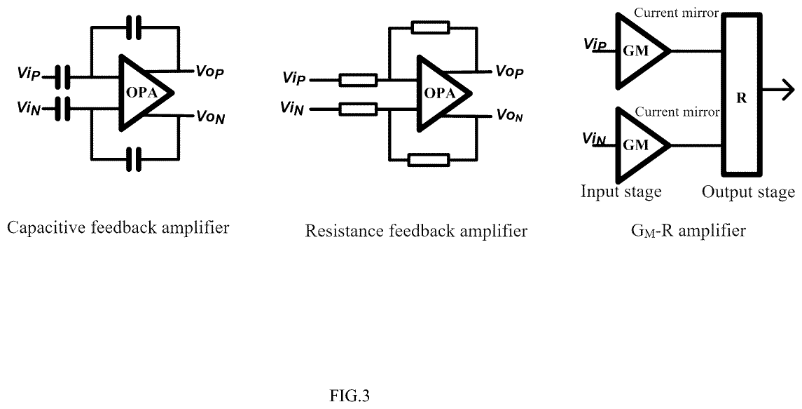

As shown in FIG. 3, an existing residue amplifier structure mainly includes a closed-loop amplifier based on capacitive feedback, a closed-loop amplifier based on resistance feedback, and an open-loop amplifier based on G_{M}-R. Most two-stage SAR ADCs use the closed-loop amplifier based on capacitive feedback as the residue amplifier. Although a constant gain can be achieved, the on-chip area is large, resulting in a high cost. The residue amplifier of the two-stage SAR ADC can also be achieved by using the closed-loop amplifier based on resistance feedback. However, as the input of the residue amplifier is connected to a capacitor top plate of a digital to analog converter (DAC) in the first-stage sub-ADC, charges stored in the DAC will be leaked along a resistance feedback network. Therefore, when the structure is applied, it is often needed to arrange an extra buffer stage additionally. The open-loop amplifier based on G_{M}-R avoids charge leakage by connecting the output of the digital to analog converter to an MOS grid electrode. However, its stability is inferior to that of the closed-loop amplifier.

The residue amplifier structure used in this application is achieved based on a circuit of the difference and differential amplifier; a working process of the two-stage SAR ADC based on a difference and differential amplifier includes: first, roughly digitizing a differential input signal and generating a residual voltage through the first-stage sub-ADC; then amplifying the residual voltage through the difference and differential amplifier; then further digitalizing the residual voltage through the second-stage sub-ADC; and finally, correcting and combining outputs of the two sub-ADCs in an output circuit to generate a 16-bit digital output.

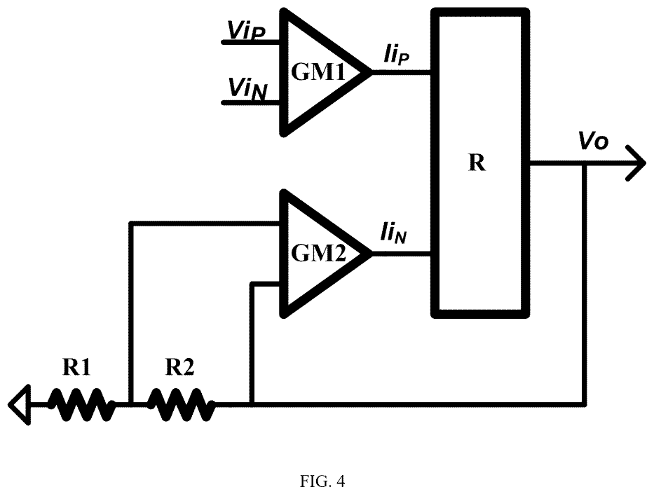

As shown in FIG. 4, the difference and differential amplifier includes a transconductance amplifier GM1, a transconductance amplifier GM2, a resistance load R and proportional resistors R1 and R2, the transconductance amplifier GM1, the resistance load R, and the transconductance amplifier GM2 form a negative feedback loop, and the proportional resistors R1 and R2 are configured to regulate gains of the amplifiers;
the capacitor array of the first-stage sub-ADC is serially connected to the transconductance amplifier GM1, the resistance load R, and the capacitor array of the second-stage ADC in sequence, a switch S1 is arranged at an input end of the capacitor array of the first-stage sub-ADC, a switch S2 is arranged at input end of the capacitor array of the second-stage sub-ADC, the proportional resistors R1 and R2 are serially connected in a signal grounding circuit, a voltage signal of the transconductance amplifier GM2 is in receiving connection to the voltages at both ends of any one of the proportional resistors R1 and R2, and a current signal of the transconductance amplifier GM2 is in output connection to the resistance load R;
a specific working process of the difference and differential amplifier includes: first, converting the residual voltage that is generated by the first-stage sub-ADC and passes through the transconductance amplifier GM1 into a current signal Ii_{P}; then passing the current signal lip through the resistance load R and outputting a voltage signal V_{O}; and finally, by taking the V_{O} divided by the proportional resistors R1 and R2 as an input of the transconductance amplifier GM2, outputting a Ii_{N} to regulate a current flowing through the resistance load, so as to regulate an output voltage V_{O}.

The output currents of the transconductance amplifier GM1 and the transconductance amplifier GM2 are respectively:

$${Ii}_{P} = {G}_{m 1} \cdot ( {V i}_{P} - {V i}_{N} )$$

$${Ii}_{N} = - V o \cdot \frac{R 2}{R 1 + R 2} \cdot {G}_{m 2}$$

where Gₘ₁ and Gₘ₂ respectively represent transconductance values of the transconductance amplifier GM1 and the transconductance amplifier GM2.

The output voltage of the difference and differential amplifier is:

$$V o = R \cdot ( {Ii}_{P} + {Ii}_{N} )$$

the gain of the difference and differential amplifier is:

$$Gain = \frac{{G}_{m 1}}{\frac{1}{R} + \frac{R 2}{R 1 + R 2} \cdot {G}_{m 2}}$$

in a case that 1/Gₘ₁=1/Gₘ₂<<R, the above equation can be simplified as:

$$Gain \approx 1 + \frac{R 1}{R 2}$$

where the gain of the amplifier is flexibly regulated by regulating a resistance proportion of R1 and R2.

Specific working steps based on the above architecture are as follows:
step I, switching on a switch S1, where signal voltages are stored in the capacitor arrays of the first-stage sub-ADC;
step II, switching off the switch S1, where the capacitor arrays of the first-stage sub-ADC will be flipped in sequence, charges stored in the capacitor arrays will be redistributed, and a voltage difference between input ends of the transconductance amplifier GM1 will be gradually decreased;
step III, in a case that a last pair of capacitors in the capacitor array of the first-stage sub-ADC are flipped, switching on a switch S2, where the capacitor array of the second-stage sub-ADC will store a voltage outputted by a residue amplifier;
step IV, switching off the switch S2, where the capacitor arrays of the second-stage sub-ADC will be flipped in sequence to redistribute the charges and reduce the voltage difference; and
step V, integrating flipping conditions of the capacitor arrays of the first-stage and second-stage sub-ADCs to output a finally quantified signal.

The above description is merely the preferred implementations of the disclosure. It shall be pointed out that a person of ordinary skill in the art still can make several improvements and embellishments without departing from the above principle of the disclosure, and these improvements and embellishments shall also be regarded within the protection scope of the disclosure.

1. A two-stage successive approximation register analog to digital converter based on a difference and differential amplifier, comprising a first-stage sub-ADC, a difference and differential amplifier, and a second-stage sub-ADC connected in sequence, wherein the first-stage sub-ADC and the second-stage sub-ADC each comprise capacitor arrays and comparators; and further comprising a calibrating circuit and a digital logic control circuit, wherein the calibrating circuit is configured for one-time calibration of offset voltages of each of the amplifiers and the comparators, and the digital logic control circuit is configured to control work schedules of the two sub-ADCs;
the difference and differential amplifier comprises a transconductance amplifier GM1, a transconductance amplifier GM2, a resistance load R, and proportional resistors R1 and R2;
the transconductance amplifier GM1, the resistance load R, and the transconductance amplifier GM2 form a negative feedback loop, and the proportional resistors R1 and R2 are configured to regulate gains of the amplifiers; and
specific working steps based on the above architecture are as follows:
step I, switching on a switch S1, wherein signal voltages are stored in the capacitor arrays of the first-stage sub-ADC;
step II, switching off the switch S1, wherein the capacitor arrays of the first-stage sub-ADC will be flipped in sequence, charges stored in the capacitor arrays will be redistributed, and a voltage difference between input ends of the transconductance amplifier GM1 will be gradually decreased;
step III, in a case that a last pair of capacitors in the capacitor array of the first-stage sub-ADC are flipped, switching on a switch S2, wherein the capacitor array of the second-stage sub-ADC will store a voltage outputted by a residue amplifier;
step IV, switching off the switch S2, wherein the capacitor arrays of the second-stage sub-ADC will be flipped in sequence to redistribute the charges and reduce the voltage difference; and
step V, integrating flipping conditions of the capacitor arrays of the first-stage and second-stage sub-ADCs to output a finally quantified signal.

2. The two-stage successive approximation register analog to digital converter based on a difference and differential amplifier according to claim 1, wherein a working process of the two-stage successive approximation register analog to digital converter based on a difference and differential amplifier comprises: first, roughly digitizing a differential input signal and generating a residual voltage through the first-stage sub-ADC; then amplifying the residual voltage through the difference and differential amplifier; then further digitalizing the residual voltage through the second-stage sub-ADC; and finally, correcting and combining outputs of the two sub-ADCs in an output circuit to generate a 16-bit digital output.

3. The two-stage successive approximation register analog to digital converter based on a difference and differential amplifier according to claim 2, wherein a specific working process of the difference and differential amplifier comprises: first, converting the residual voltage that is generated by the first-stage sub-ADC and passes through the transconductance amplifier GM1 into a current signal IiP; then passing the current signal IiP through the resistance load R and outputting a voltage signal VO; and finally, by taking the VO divided by the proportional resistors R1 and R2 as an input of the transconductance amplifier GM2, outputting a IiN to regulate a current flowing through the resistance load, so as to regulate an output voltage Vo.

4. The two-stage successive approximation register analog to digital converter based on a difference and differential amplifier according to claim 3, wherein the output currents of the transconductance amplifier GM1 and the transconductance amplifier GM2 are respectively:
$${Ii}_{P} = {G}_{m 1} \cdot ( {V i}_{P} - {V i}_{N} ) ; {Ii}_{N} = - V o \cdot \frac{R 2}{R 1 + R 2} \cdot {G}_{m 2} ,$$
wherein Gm1 and Gm2 respectively represent transconductance values of the transconductance amplifier GM1 and the transconductance amplifier GM2.

5. The two-stage successive approximation register analog to digital converter based on a difference and differential amplifier according to claim 4, wherein the output voltage of the difference and differential amplifier is:
$$V o = R \cdot ( {Ii}_{P} + {Ii}_{N} ) .$$

6. The two-stage successive approximation register analog to digital converter based on a difference and differential amplifier according to claim 5, wherein the gain of the difference and differential amplifier is:
$$Gain = \frac{{G}_{m 1}}{\frac{1}{R} + \frac{R 2}{R 1 + R 2} \cdot {G}_{m 2}} ;$$
in a case that 1/Gm1=1/Gm2<<R, the above equation can be simplified as:
$$Gain \approx 1 + \frac{R 1}{R 2} ,$$
wherein the gain of the amplifier is flexibly regulated by regulating a resistance proportion of R1 and R2.
